(19) United States
(12) Patent Application Publication
(10) Pub. No.: US 2014/0247435 A1
(43) Pub. Date: Sep. 4, 2014

(54) RADIATION SOURCE DEVICE, LITHOGRAPHIC APPARATUS, AND DEVICE MANUFACTURING METHOD

(71) Applicant: ASML Netherlands B.V., Veldhoven (NL)

(72) Inventor: Martinus Coenen, Eindhoven (NL)

(73) Assignee: ASML Netherlands B.V., Veldhoven (NL)

(21) Appl. No.: 14/351,917

(22) PCT Filed: Oct. 23, 2012
(86) PCT No.: PCT/EP2012/070978

§ 371 Date: Apr. 15, 2014

Related U.S. Application Data
(60) Provisional application No. 61/560,020, filed on Nov. 15, 2011.

(51) Int. Cl. G03F 7/20

(52) U.S. Cl. CPC G03F 7/70341; G03F 7/70058
USPC 355/30; 355/67; 355/77

(57) ABSTRACT

In a discharge-produced plasma source, a pair of electrodes is charged using a transmission line. In an embodiment, a pair of transmission lines may be used, connected symmetrically to the electrodes. The impedance of the transmission lines, or the total impedance of the transmission lines, is equal to that of the discharge in an embodiment. Use of a transmission line provides longer discharge pulses with more consistent potential difference.

### CROSS REFERENCE TO RELATED APPLICATIONS

This application claims the benefit of U.S. provisional application 61/560,020, which was filed on Nov. 15, 2011 and which is incorporated herein in its entirety by reference.

### FIELD

The present invention relates to a radiation source device constructed and arranged to generate radiation, a lithographic apparatus comprising such a radiation source device, and a device manufacturing method.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured. A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

EUV radiation may be produced using a plasma. A radiation source device for producing EUV radiation may include a laser for exciting a fuel to provide the plasma, and a source collector apparatus for containing the plasma. The plasma may be created, for example, by directing a laser beam at a fuel, such as particles of a suitable material (e.g. tin), or a stream of a suitable gaseous medium provided by a medium supply. By gaseous medium herein is meant fuel in form of gas or vapor, such as Xe gas or Li vapor. The medium supply may be arranged to provide the gaseous medium to a specific location in the radiation source device. The resulting plasma emits output radiation, e.g., EUV radiation, which is collected using a radiation collector. The radiation collector may be a mirrored normal or grazing incidence radiation collector, which receives the radiation and focuses the radiation into a beam. The source collector apparatus may include an enclosing structure or chamber arranged to provide a vacuum environment to support the plasma. Such a radiation system is typically termed a laser produced plasma (LPP) source.

A discharge produced (DPP) source generates plasma by a discharge in a medium, for example a gas or vapor, between two electrodes (an anode and a cathode), and may subsequently create a high-temperature discharge plasma by Ohmic heating caused by a pulsed current flowing through the plasma. In this case, the desired radiation is emitted by the high-temperature discharge plasma. During operation, the EUV radiation is generated by creating a pinch.

Generally, a plasma is formed by a collection of free-moving electrons and ions (atoms that have lost electrons). The energy used to strip electrons from the atoms to make plasma can be of various origins: thermal, electrical, or light (ultraviolet light or intense visible light from a laser). More details on the pinch, the laser triggering effect and its application in a source with rotating electrodes may be found in J. Pankert, G. Derra, P. Zink, Status of Philips' extreme-UV source, SPIE Proc. 6151-25 (2006) (hereinafter “Pankert et al.”).

A known practical discharge produced plasma EUV source comprises a pair of rotating disk shaped electrodes that are each partly immersed in a respective liquid bath comprising liquid fuel. The electrodes are rotated so that liquid from the liquid baths is carried along the surfaces of the electrodes. An ignition source is configured to trigger a discharge produced radiating plasma from liquid adherent to the electrode, by a discharge at a location between the first electrode and the second electrode. Typically, one electrode is at a negative potential while the other one is at ground or a positive potential. The electrode gap may be relatively small, e.g. of the order of few millimeters, to comply with the Paschen requirements to cause an arc across the gap. Such a discharge source emits pulses of radiation, each time the discharge occurs. The amount of useful radiation produced depends on the voltage of the across the electrodes during the discharge and the duration of the pulse.

### SUMMARY

It is desirable to increase the useful power of an EUV source.

According to as aspect of the present invention, there is provided a radiation source device constructed and arranged to generate radiation by using an electrical discharge through a gaseous medium, the device comprising: a first electrode and a second electrode; a medium supply arranged to provide the gaseous medium to a location in the device; and a charging device arranged to generate a potential difference between the first electrode and the second electrode in order to allow the electrical discharge to be generated in an electrical field created by the potential difference, the electrical discharge producing a radiating plasma; wherein the charging device comprises a transmission line.

### BRIEF DESCRIPTION OF THE DRAWINGS

These and other aspects are described in more detail with reference to the drawings, in which:

FIG. 1 depicts a lithographic apparatus according to an embodiment of the invention;

FIG. 2 is a more detailed view of the apparatus of FIG. 1;

FIG. 3 shows a side view of a device constructed and arranged to generate radiation;

FIG. 4 schematically shows a top-view of the device of FIG. 3 taken from vantage point B;

FIG. 5 is a schematic circuit diagram of a charging device according to an embodiment of the invention;

FIG. 6 is a graph of voltage across and current through the discharge over time in a simulation of the circuit of FIG. 5;

FIG. 7 is a graph showing part of the graph of FIG. 6 with an expanded time axis;

FIG. 8 is a schematic circuit diagram of a charging device according to an embodiment of the invention;

FIG. 9 is a graph of voltage across and current through the discharge over time in a simulation of the circuit of FIG. 8;

FIG. 10 is a graph showing part of the graph of FIG. 9 with an expanded time axis;

FIG. 11 is a schematic circuit diagram of a charging device according to an embodiment of the invention;

FIG. 12 is a graph of voltage across and current through the discharge over time in a simulation of the circuit of FIG. 11;

FIG. 13 is a graph showing part of FIG. 12 with an expanded time axis; and

FIG. 14 is a schematic view depicting a transmission line used in an embodiment of the invention.

### DETAILED DESCRIPTION

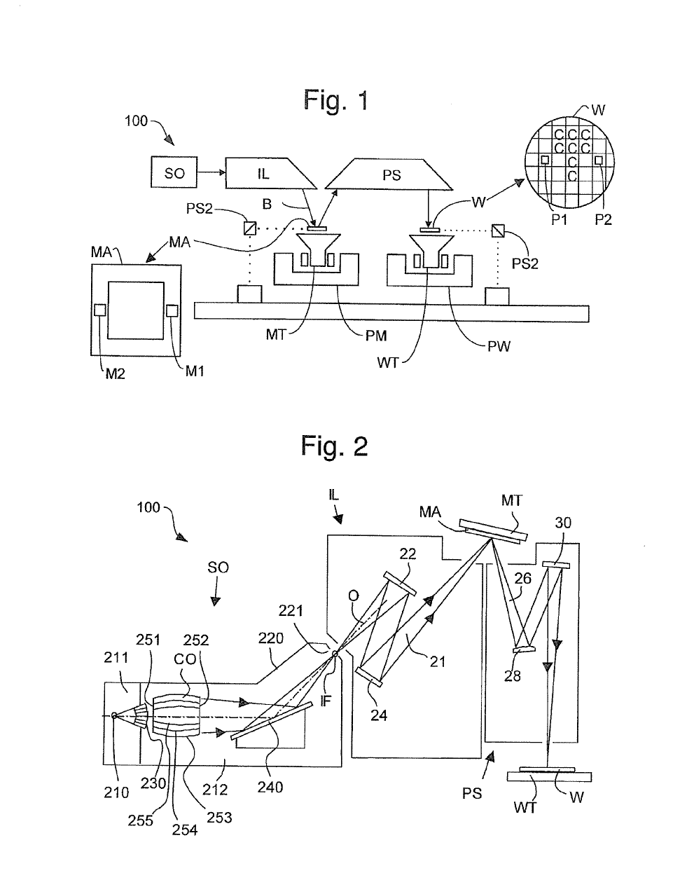

FIG. 1 schematically depicts a lithographic apparatus 100 including a source collector apparatus SO according to one embodiment of the invention. The apparatus comprises: an illumination system (illuminator) IL configured to condition a radiation beam B (e.g. EUV radiation); a support structure (e.g. a mask table) MT constructed to support a patterning device (e.g. a mask or a reticle) MA and connected to a first positioner PM configured to accurately position the patterning device; a substrate table (e.g. a wafer table) WT constructed to hold a substrate (e.g. a resist-coated wafer) W and connected to a second positioner PW configured to accurately position the substrate; and a projection system (e.g. a reflective projection system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable minor array employs a matrix arrangement of small minors, each of which can be individually tilted so as to reflect an incoming radiation beam in different directions. The tilted minors impart a pattern in a radiation beam which is reflected by the minor matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g. employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source collector apparatus SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”), the desired plasma can be produced by irradiating a fuel, such as a droplet, stream or cluster of material having the required line-emitting element, with a laser beam. The source collector apparatus SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector apparatus. The laser and the source collector apparatus may be separate entities, for example when a CO₂ laser is used to provide the laser beam for fuel excitation.

In such cases, the laser is not considered to form part of the lithographic apparatus and the radiation beam is passed from the laser to the source collector apparatus with the aid of a beam delivery system comprising, for example, suitable directing mirrors and/or a beam expander. In other cases, the source may be an integral part of the source collector apparatus, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil minor devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS 1 can be used to accurately position the patterning device (e.g. mask) MA with respect to the path of the radiation beam B. Patterning device (e.g. mask) MA and substrate W may be aligned using mask alignment marks M1, M2 and substrate alignment marks P1, P2.

The depicted apparatus could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIG. 2 shows the apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. The contaminant trap 230 may also include a gas barrier or a combination of a gas barrier and a channel structure. The contaminant trap or contaminant barrier 230 further indicated herein at least includes a channel structure, as known in the art.

The collector chamber 212 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector apparatus is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil minor device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be from one to six additional reflective elements present in the projection system PS than shown in FIG. 2.

Collector optic CO, as illustrated in FIG. 2, is depicted as a nested collector with grazing incidence reflectors 253, 254 and 255, just as an example of a collector (or collector minor). The grazing incidence reflectors 253, 254 and 255 are disposed axially symmetric around an optical axis O and a collector optic CO of this type is advantageously used in combination with a discharge produced plasma source, often called a DPP source.

Referring to the radiation source device SO (also termed below as radiation source) in FIGS. 1 and 2, a typical (tin-based) plasma discharge sources consists of two rotating wheels on which liquid tin is continuously applied, e.g. by partly immersing them in a liquid tin bath as discussed in Pankert et al. cited above. The wheels act as electrodes and a discharge is established at the point where the wheels are closest to one another. Instead of a tin based plasma source, several other fuel sources may be used to generate EUV radiation at a wavelength of 13.5 nm, including xenon, and lithium. Tin is often preferred for production tool specifications because of its high conversion efficiency.

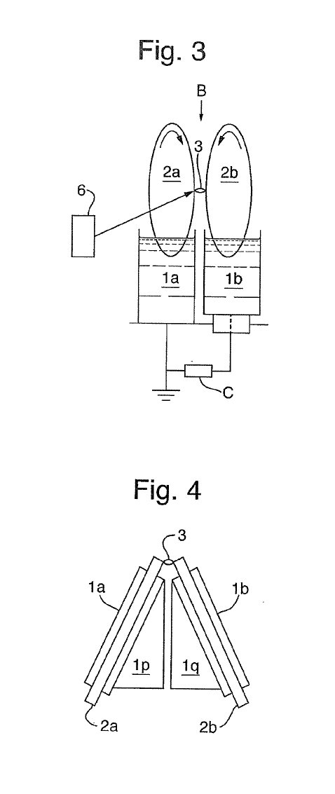

FIGS. 3 and 4 show such a known radiation source, e.g. a tin-based EUV source with rotating disk electrodes. The prior art source comprises two liquid baths 1a and 1b through which respective electrodes 2a and 2b are rotated. In this example, each of the baths 1a, 1b contains liquid tin, and therefore may be called liquid tin baths. However, other liquids, like gallium, indium, lithium or any combination thereof may be used instead of or in addition to tin. The baths 1a, 1b are thermally coupled to respective heating elements arranged in housings 1p, 1q. The heating elements serve to melt the tin at start-up of the device. Such a liquid bath 1a, 1b and the corresponding rotating disc electrode 2a, 2b partially immersed in the liquid bath are together an example of a medium supply.

During normal operation of the device the heating elements are switched off and the housings 1p, 1q serve to conduct heat from the baths 1a, 1b to a heat sink. One bath 1a is connected to a negative potential, the other bath 1b is at ground or a positive potential. During normal operation of the source, tin is evaporated from one of the electrodes by an ignition source 6, which may be a laser such as a pulsed trigger laser, and the discharge is subsequently established through the tin vapor at discharge location 3 in a gap between the first electrode and the second electrode. The gap has a width of few millimeters, to comply with Paschen requirements to provide an arc across the electrodes. Tin debris may be emitted from different positions along the discharge: micro particles originate mainly at the electrode surface, while most of the atomic and ionic debris comes from the pinch (between the electrodes). In an embodiment, an electron beam generator is used instead of the pulsed trigger laser 6.

In an embodiment, the device may have only one electrode that rotates in a liquid bath, while another electrode may be arranged statically. In that case, the rotating electrode carries the liquid from the bath towards the discharge location 3. The statically arranged electrode may, however, wear relatively fast during operation due to the discharge striking at its surface. Both electrodes 2a, 2b may be implemented as rotating in a liquid bath, since in that case the discharge strikes at the liquid carried along at the surface of the electrode from the liquid bath. Furthermore, the rotation of the electrodes 2a, 2b through the liquid baths 1a, 1b provides for a cooling of the electrodes 2a, 2b. Typically the tin bath will be cooler (for example: below 300° C.) than the electrode (typically up to 800° C.) and may therefore provide substantial cooling by thermal conduction.

The ignition source 6 is configured to trigger a discharge-produced radiating plasma from liquid adherent to the electrode, by a discharge at the discharge location 3.

Typical parameters for the ignition source 6, particularly when the ignition source is a trigger laser, may include an energy per pulse Q of approximately from 10 to 100 mJ for a tin discharge and approximately 1 to 10 mJ for a lithium discharge, a duration of the pulse of τ=about 1 to 100 ns, a laser wavelength of λ=about 0.2 to 10 μm, at a repetition frequency of about 5-100 kHz. The ignition source 6 may produce a laser beam directed to the electrode 2b to vaporise the adherent liquid provided from liquid bath 1b.

Thereby, liquid material on the electrode 2b may be evaporated to form a gaseous medium and pre-ionized at a well-defined location 3, i.e. the location where the laser beam hits the electrode 2b. From that location, a discharge towards the electrode 2a may develop. The precise location 3 of the discharge can be controlled by the ignition source 6. This is desirable for the stability, i.e. homogeneity, of output of the source device and may have an influence on the constancy of the radiation power of the device. This discharge generates a current between the electrodes 2a, 2b. The current induces a magnetic field. The magnetic field generates a pinch, or compression, in which ions and free electrons are produced by collisions. Some electrons will drop to a lower band than the conduction band of atoms in the pinch and thus produce radiation. When the liquid material is chosen from gallium, tin, indium or lithium or any combination thereof, the radiation includes large amounts of EUV radiation. The radiation emanates in all directions and may be collected by a radiation collector in the illuminator IL of FIG. 1. The ignition source 6 may provide a pulsed laser beam.

The radiation is isotropic at least at angles to a Z-axis with an angle θ in the range from about 45 to about 105°. The Z-axis refers to the axis aligned with the pinch and going through the electrodes 2a, 2b and the angle θ is the angle with respect to the Z-axis. The radiation may be isotropic at other angles as well.

Instead of a liquid bath, the device for generating radiation may comprise an alternative liquid supply such as a droplet injector that injects the droplets between the electrodes, as is described for example in Proceedings of SPIE—Volume 6517 Emerging Lithographic Technologies XI, Michael J. Lercel, Editor, 65170P (Mar. 15, 2007). The injection of droplets in-between the wheels may increase the electric field strength, which can be used to start the discharge without the need for a laser or any other (electron beam) stimulus to start the discharging process.

Radiation is emitted by the plasma when ionized atoms of the liquid material recombine with free electrons. The wavelengths of the radiation produced therefore depend on the states into which the recombining electrons go. To obtain EUV radiation using tin as the plasma material, it is desirable to fully ionize the tin atoms, i.e. strip off all electrons. This may require that the potential difference across the plasma is greater than a critical voltage, for example about 2,700 V. If different materials are used to form the plasma or different wavelengths are desired, the critical voltage might be different. If the potential difference is less than the critical voltage, the tin atoms are only partially ionized and the recombining electrons emit radiation at longer wavelengths.

In previously proposed sources using capacitors to charge the electrode prior to discharge, the profile of the potential difference across the electrodes during the discharge is an exponential decay. Thus, the potential difference quickly drops below the critical voltage, within a few nanoseconds, and useful radiation is no longer produced. There is thus a need to improve the efficiency of such EUV source. Also, the resistance of the plasma varies, affecting the rate of decay of the potential difference between the electrodes and making the useful energy content of the pulse less predictable. An improved source is desirable, for example having at least one of: greater efficiency, higher useful energy per pulse, longer pulse duration, and more predictable useful energy per pulse.

In an embodiment of the present invention, one or more transmission lines are used to charge the electrodes that drive the discharge Transmission lines use specialized construction such as precise conductor dimensions and spacing, and impedance matching, to carry electromagnetic signals with minimal reflections and power losses. Types of transmission line include ladder line, coaxial cable, dielectric slabs, stripline, optical fiber, and waveguides. The higher the frequency, the shorter are the waves in a transmission medium. Transmission lines are needed when the frequency is high enough that the wavelength of the waves begins to approach the length of the cable used. A transmission line can be for example defined herein as a pair of conductors having a length that is not negligible compared to the wavelength of the signals propagating along them, i.e. their wave nature is taken into account. In the case of a pulse discharge, the effective wavelength is the product of the pulse duration and the speed of a travelling wave in the transmission line, which is determined by the characteristic impedance thereof. Use of a transmission line in this way may provide an advantage that the potential difference between the electrodes remains constant during the discharge of the transmission line. The duration of the discharge is determined by the length of the transmission line, the length being related to a propagation delay. The discharge duration is about two times the propagation delay of the transmission line. Thus, embodiments of the invention can provide a longer pulse of useful radiation, greater useful energy per pulse, a higher duty ratio and/or a more predictable energy per pulse.

The length, i.e. propagation delay, of the transmission line determines the time taken for it to discharge and therefore the length of the pulse. A standard coaxial transmission line of length 1 m gives for example a pulse of approximately 7 ns. In an embodiment using conventional insulating material, the transmission line is about 4 m or greater in length. In an embodiment, the transmission line is equal to or greater than about 5 m in length. The maximum length of the transmission line may be determined by the available charging current—a longer line holds more energy and takes longer or more current to charge—and the space available for the transmission line in the apparatus. In an embodiment, the length of the transmission line is less than or equal to 10 m. In an embodiment in which an insulating dielectric with a high permittivity is used, the length of transmission line can be shorter. For example, using demineralized water (∈ᵣ=80) a transmission line of 1.7 m gives a propagation delay of 50 ns, and a pulse length of 100 ns. A transmission line 80 in an embodiment of the invention is depicted schematically in FIG. 14. The transmission line comprises a first conductor 81 separated by a dielectric material 82 from a second conductor 83. The dimension of the conduction and the thickness of the dielectric material 82 are chosen according to the propagation delay desired and the relative permittivity ∈ᵣ of the dielectric material, desirably ∈ᵣ≧10, more desirably ∈ᵣ≧70. Preferably, the transmission line (or each, if more present) has a propagation delay greater than 20 ns, more preferably greater than 30 ns and even more preferably greater than 50 ns. Preferably, the transmission line (or each, if more present) has a propagation delay less than 200 ns, more preferably less than 150 ns and even more preferably less than 100 ns.

In an embodiment the transmission line takes the form of a pair of metal foils having dimensions of for example 7 m by 0.3 m, separated by a dielectric material. The foils may be folded or wound up into a convenient form. The transmission line can also be provided with frame conductors that are connected to ground or a frame of the device. In an embodiment, the frame conductors are provided outside the anode and cathode conductors. In an embodiment, a third frame conductor is also provided, between the anode and cathode conductor. In an embodiment, the transmission line is immersed in oil, demineralized water or another insulating liquid (which may also provide cooling).

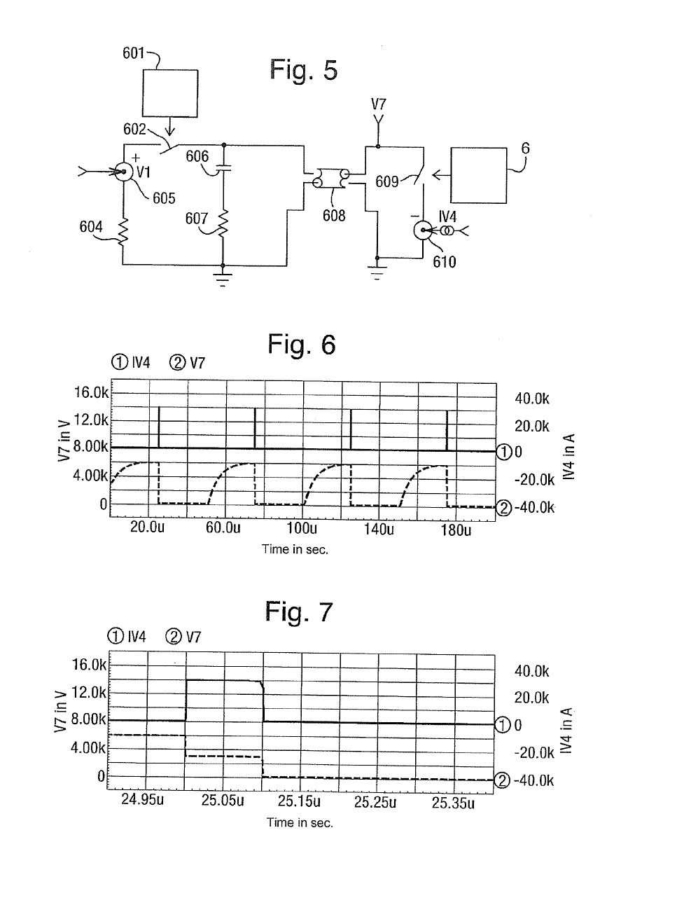

FIG. 5 is a schematic circuit diagram of an embodiment of the invention. DC high voltage source 605 provides a high voltage V1, e.g. of 6 kV, to charge the transmission line 608. Voltage source 605 may be formed as a single ended source or two differential sources. When control switch 602 is closed by controller 601, the voltage source 605 charges transmission line 608 through resistor 604. Transmission line 608 has an impedance of about 0.1Ω, while resistor 604 has a resistance or a current limiting impedance of about 10Ω. This means that resistor 604 limits the current that charges the transmission line 608. Capacitor 606 having a capacitance of about 1 nF and resistor 607 of about 0.1Ω prevent reflections from the transmission line 608 back to voltage source 605. The circuitry to the right of transmission line 608 represents the electrode arrangement. Switch 609 represents the discharge which is triggered by trigger device 6. When the discharge is triggered, a current flows through the plasma between electrodes 610, represented by current IV4.

FIG. 6, which depicts results obtained from simulations of the circuit shown in FIG. 5, shows the behavior of the corresponding device. As can be seen, over a period of about 25 μs (on the horizontal axis), the voltage across the electrode side of transmission line 608, represented by V7 (see dashed line 2), rises from 0 to about 6 kV. When the transmission line voltage has reached the desired value, the discharge is triggered, in this embodiment by laser trigger device 6. This causes a brief pulse of current across the electrodes as the voltage in the transmission line discharges. A single pulse is shown with time scale magnified in FIG. 7.

In FIG. 7 it can be seen that the voltage across the transmission line drops to half its fully charged version as the discharge begins and then remains stable at that level until the transmission line 608 is fully discharged. This means that there is a constant current at constant voltage through the discharge for an extended period of time. With typical values of charging source equal to 6 kV and equivalent impedance of the discharge of 100 mΩ, the current through the discharge is equal to about 30 kA. The pulse lasts about 100 nanosecond and has a total value of about 9.0 kJ per pulse. As seen in FIG. 6, a 20 kHz or higher repetition rate, i.e. 50 μs period, can readily be achieved.

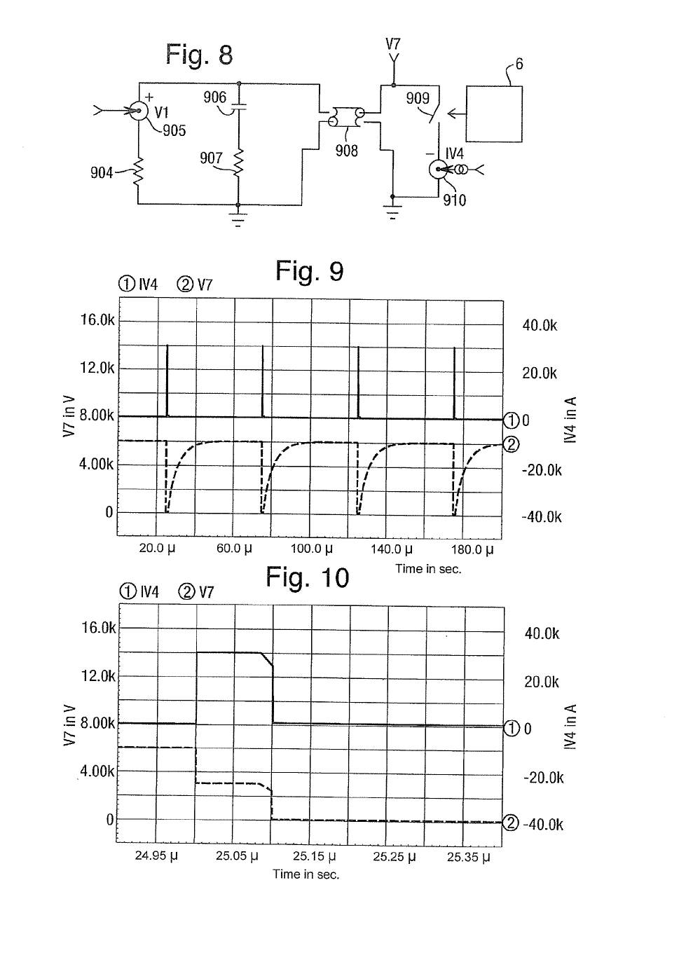

FIG. 8 illustrates a variation of the invention in which the high voltage DC design is simplified by providing continuous charging of the transmission line. Otherwise, this embodiment is the same as the circuit of FIG. 5. Components in FIG. 8 beginning with the digit “9” are the same corresponding by number component in FIG. 5 beginning with digit “6”.

FIGS. 9 and 10 are graphs similar to FIGS. 6 and 7. It can be seen that the voltage V7 across the electrodes quickly achieves its maximum value of about 6 kV and stays there until the discharge is triggered by the trigger device. It then returns to the maximum value as in the circuit of FIG. 5. The expanded view of a single pulse shown in FIG. 10 illustrates essentially the same behavior, with the voltage across the electrodes dropping to 50% of the maximum charged voltage as soon as the discharge begins but then remaining stable for most of the period of the pulse.

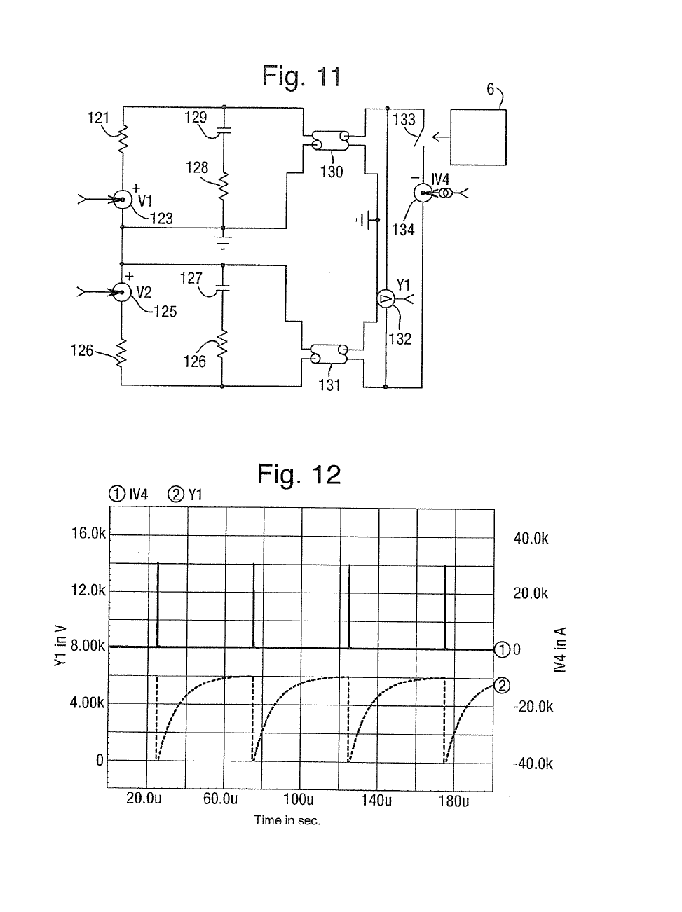

A further alternative arrangement is shown in FIG. 11. This uses two transmission lines 130, 131 and two symmetrical DC sources 123, 125 which are arranged symmetrically relative to the two electrodes. Both DC sources 123, 125 provide 3 kV outputs. In this arrangement, there are no discharge currents through ground or the frame as the discharge voltage is symmetrical. This means that the high voltage stress on the insulation used is halved and the flow of discharge currents through the frame is prevented. Each transmission line 130, 131 has half the impedance of the discharge, e.g. 50 mΩ. Resistors 121, 126 limit the charging currents drawn from high voltage sources 123, 125 and in an embodiment have resistances of 5Ω R-C pairs 128, 129 and 126, 127 prevent reflections from the transmission lines. In an embodiment, capacitors 127, 129 have capacitors of 1 nF and resistors 126, 128 have a resistance of 50 mΩ. The circuitry to the right of the transmission lines 130, 131 represents the electrode arrangement. The voltage across the electrode side of the transmission lines 130, 131 is represented by Y1 at 132. Switch 133 represents the discharge which is triggered by trigger device 6. When the discharge is triggered, a current flows through the plasma between the electrodes 134, represented by current IV4.

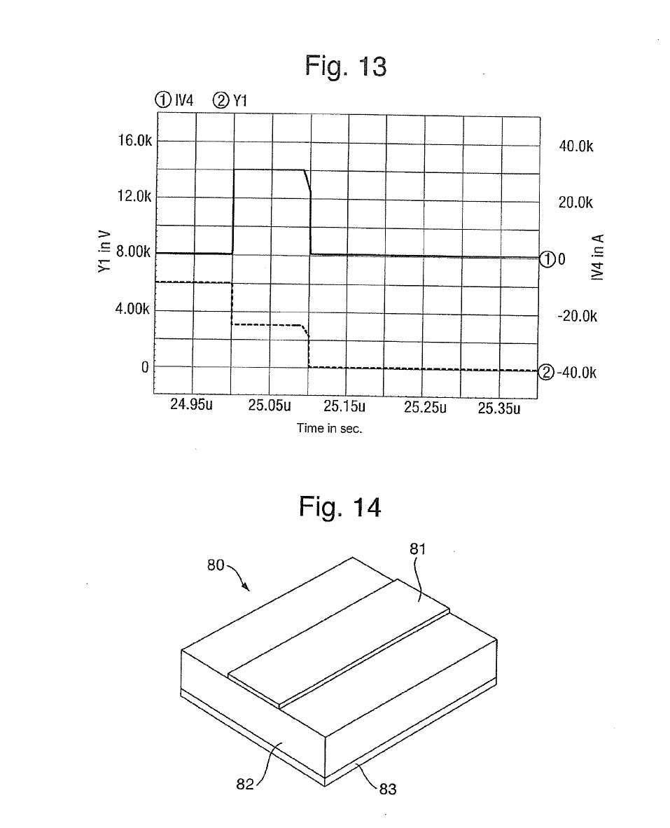

Again it can be seen from FIGS. 12 and 13 that the behavior of this source is essentially the same of the earlier embodiments.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein. The descriptions above are intended to be illustrative, not limiting. Thus it will be apparent to one skilled in the art that modifications may be made to the invention as described without departing from the scope of the claims set out below.

1. A radiation source device constructed and arranged to generate EUV radiation by using an electrical discharge through a gaseous medium, the radiation source device comprising:
a first electrode and a second electrode;
a medium supply arranged to provide the gaseous medium to a location in the device; and
a charging device arranged to generate a potential difference between the first electrode and the second electrode in order to allow the electrical discharge to be generated in an electrical field created by the potential difference, the electrical discharge producing a radiating plasma, wherein the charging device comprises a transmission line having a propagation delay greater than 50 ns.

2. A device according to claim 1, wherein the charging device further comprises a high voltage DC source having an output voltage greater than twice a voltage required to ionize the gaseous medium sufficiently to emit radiation of a desired wavelength.

3. A device according to claim 1, wherein the charging device comprises two DC sources and two transmission lines, the DC sources and the transmission lines being symmetrically connected to the first and second electrodes.

4. A device according to claim 3, wherein the two DC sources have output voltages greater than a voltage required to ionize the gaseous medium sufficiently to emit radiation of a desired wavelength.

5. A device according to claim 1, wherein the transmission line has an impedance substantially equal to the impedance of the discharge.

6. A device according to claim 3, wherein the transmission line has an impedance substantially equal to half the impedance of the discharge.

7-9. (canceled)

10. A device according to claim 1, wherein the transmission line has a propagation delay less than 200 ns.

11. A device according to claim 10, wherein the propagation delay is less than 150 ns.

12. A device according to claim 11, wherein the propagation delay is less than 100 ns.

13. A device according to claim 1, wherein the transmission line comprises conductors separated by a dielectric, the dielectric having a relative permittivity greater than or equal to 10.

14. A device according to claim 1, further comprising an ignition source configured to at least partially evaporate a liquid to form the gaseous medium.

15. A device according to claim 14, wherein the ignition source is configured to generate a beam of laser radiation and/or an electron beam to trigger the discharge.

16. A device according to claim 14, wherein the medium supply comprises a liquid supply in the form of at least one bath, at least one of the electrodes being a rotating electrode partially immersed in the at least one bath.

17. A device according to claim 1, wherein the medium supply comprises a liquid supply in the form of a liquid injector configured to inject the liquid as droplets between the first electrode and the second electrode.

18. A lithographic apparatus, comprising:
a radiation source device according to claim 1;
a substrate table configured to hold a substrate; and
a projection system configured to project a radiation beam generated by the radiation source device onto a target portion of the substrate.

19. A device manufacturing method, comprising:
supplying a gaseous medium to a location between a first electrode and a second electrode;
using a transmission line to apply a potential difference between the first electrode and the second electrode to generate a discharge through the gaseous medium at a discharge location in an electrical field created by the potential difference such that a plasma is formed and emits EUV radiation, wherein the transmission line has a propagation delay greater than 50 ns;
patterning the beam of radiation with a pattern in its cross-section; and
projecting the patterned beam of radiation onto a target portion of a substrate.

20. A method according to claim 19, further comprising:
supplying a liquid to the first electrode and/or second electrode by moving the first electrode and/or second electrode through a liquid bath.

21. A method according to claim 20, further comprising:
at least partially evaporating the liquid to form the gaseous medium in order to trigger a discharge-produced radiating plasma from the liquid.

22. A method according to claim 19, further comprising applying an output voltage between the first and second electrodes greater than twice a voltage required to ionize the gaseous medium sufficiently to emit radiation of a desired wavelength.

23. A method according to claim 19, wherein the transmission line has a propagation delay less than 200 ns.
